(19) United States
(12) Patent Application Publication
(10) Pub. No.: US 2026/0231580 A1
(43) Pub. Date: Aug. 6, 2026

(54) LIGHT EMITTING ELEMENT SUBSTRATE AND METHOD OF MANUFACTURING THE SAME

(71) Applicant: AUO Corporation, Hsinchu City (TW)

(72) Inventors: Chih-Chun Yang, Hsinchu City (TW); Chien-Hung Kuo, Hsinchu City (TW)

(73) Assignee: AUO Corporation, Hsinchu City (TW)

(21) Appl. No.: 19/389,047

(22) Filed: Nov. 14, 2025

(30) Foreign Application Priority Data
Feb. 4, 2025 (TW) 114103945

(51) Int. Cl. H10H 29/49; H10H 29/01

(52) U.S. Cl. CPC H10H 29/49; H10H 29/012

(57) ABSTRACT

A light emitting element substrate including a substrate, a plurality of adhesive structures and a plurality of light emitting elements is provided. The adhesive structures are disposed on the substrate, and each of the adhesive structures includes two first adhesive members separated from each other. Each of the light emitting elements includes a light emitting body, at least one pad and two first diagonal regions. The two first diagonal regions are located on a bottom surface of the light emitting body and positioned on a first diagonal line. The pad includes a bottom edge and a side edge connected to each other. The two first adhesive members cover at least a portion of the corresponding two first diagonal regions and connect portions of the side edge and the bottom edge. In addition, a method of manufacturing the light-emitting element substrate is also mentioned.

### CROSS-REFERENCE TO RELATED APPLICATION

This application claims the priority benefit of Taiwan application serial no. 114103945, filed on February 04, 2025. The entirety of the above-mentioned patent application is hereby incorporated by reference herein and made a part of this specification.

### BACKGROUND

### Technical Field

The disclosure relates to a substrate and a method, and particularly relates to a light emitting element substrate and a method of manufacturing the light emitting element substrate.

### Description of Related Art

In the manufacturing process of the modern display device, an intermediate substrate is used to temporarily accommodate the light emitting elements (e.g., LEDs) of the display device. The light emitting elements are first disposed on the intermediate substrate through the adhesive, and are removed from the intermediate substrate in the subsequent processes. If the adhesive with stronger adhesion is used on the intermediate substrate, it will cause the light emitting elements to be difficult to remove from the intermediate substrate, and the light emitting elements are prone to damage during the removal process, which is disadvantageous for subsequent processes. If the adhesive with weaker adhesion is used on the intermediate substrate, it will cause the light emitting elements to be unable to stably connect with the intermediate substrate, and the light emitting elements are prone to fall off from the intermediate substrate or connect obliquely to the intermediate substrate, which is disadvantageous for subsequent processes.

### SUMMARY

The disclosure provides a light emitting element substrate that may stably maintain light emitting elements and make the light emitting elements easy to be removed.

The light emitting element substrate of the disclosure includes a substrate, a plurality of adhesive structures, and a plurality of light emitting elements. The adhesive structures are disposed on the substrate, and each of the adhesive structures includes two first adhesive members separated from each other. Each of the light emitting elements includes a light emitting body, at least one pad, and two first diagonal regions. The two first diagonal regions are located on a bottom surface of the light emitting body and located on a first diagonal line, and the pad is disposed on the bottom surface. The pad includes a bottom edge and a side edge connected to each other, and the side edge contacts the bottom surface. The two first adhesive members cover at least a portion of the corresponding two first diagonal regions and connect portions of the side edge and the bottom edge.

The method of manufacturing the light emitting element substrate of the disclosure includes providing the substrate. A mask layer is disposed on the substrate, and the mask layer forms a plurality of patterned openings. An adhesive layer is disposed on the substrate, and the adhesive layer fills the patterned openings. The plurality of light emitting elements are disposed. The light emitting elements contact the adhesive layer and the mask layer, each of the light emitting elements includes the light emitting body, the at least one pad, and the two first diagonal regions, the pad is disposed on the bottom surface of the light emitting body, the pad includes the bottom edge and the side edge connected to each other, the side edge contacts the bottom surface, and the two first diagonal regions are located on the bottom surface and located on the first diagonal line. Portions of the adhesive layer is removed to form the plurality of adhesive structures, and each of the adhesive structures includes the two first adhesive members separated from each other. The two first adhesive members of each of the adhesive structures cover at least a portion of the two first diagonal regions of each of the corresponding light emitting element and connect the portions of the side edge and the bottom edge. The mask layer is removed.

Based on the above, the first adhesive members of the light emitting element substrate of the disclosure only connect the portions of the pads of the light emitting elements to reduce the connection strength between the light emitting elements and the adhesive structure, making the light emitting elements easy to be removed to facilitate subsequent processes. The two first adhesive members connect to the two first diagonal regions of each of the light emitting elements, so that the light emitting elements are stably connected to the substrate. Thereby, the substrate may stably maintain the light emitting elements and make the light emitting elements easy to be removed from the substrate to facilitate subsequent processes.

### BRIEF DESCRIPTION OF THE DRAWINGS

FIG. 1 is a flowchart of a method of manufacturing a light emitting element substrate according to an embodiment of the disclosure.

FIG. 2 to FIG. 7 are schematic diagrams of the manufacturing process of the light emitting element substrate in FIG. 1.

FIG. 8 is a top view of the light emitting element substrate in FIG. 7.

FIG. 9 is a top view of a light emitting element substrate according to an embodiment of the disclosure.

FIG. 10 is a top view of a light emitting element substrate according to an embodiment of the disclosure.

### DESCRIPTION OF THE EMBODIMENTS

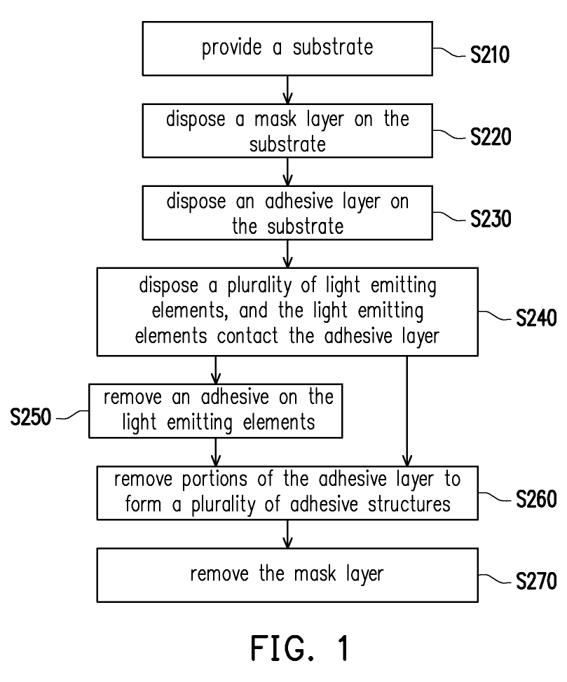

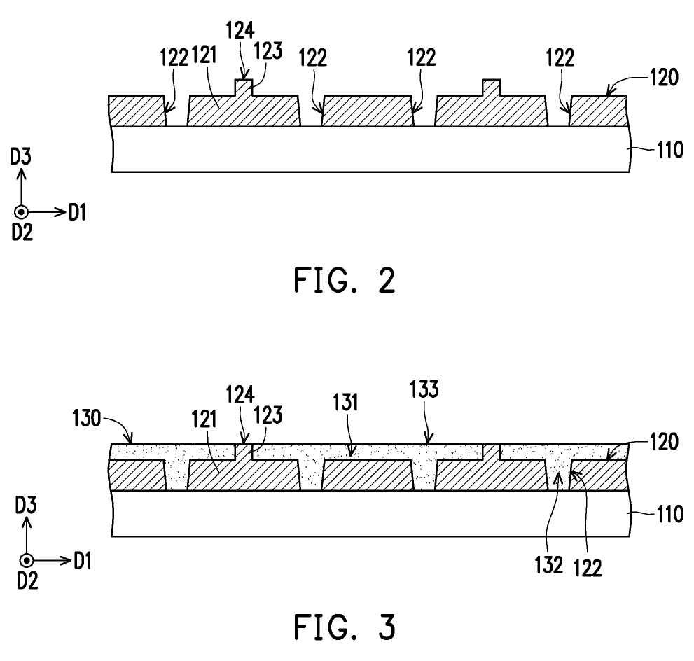

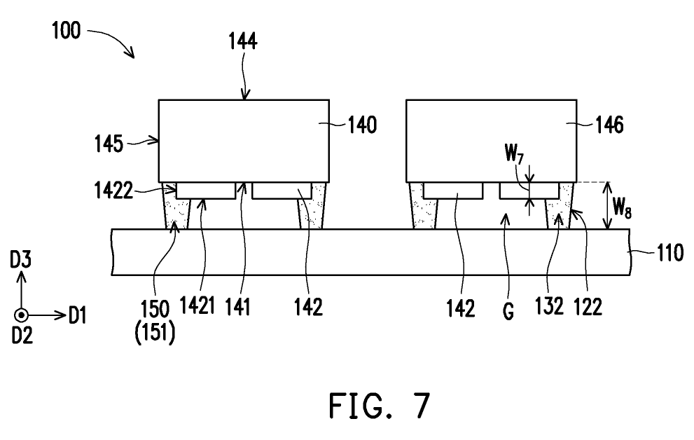

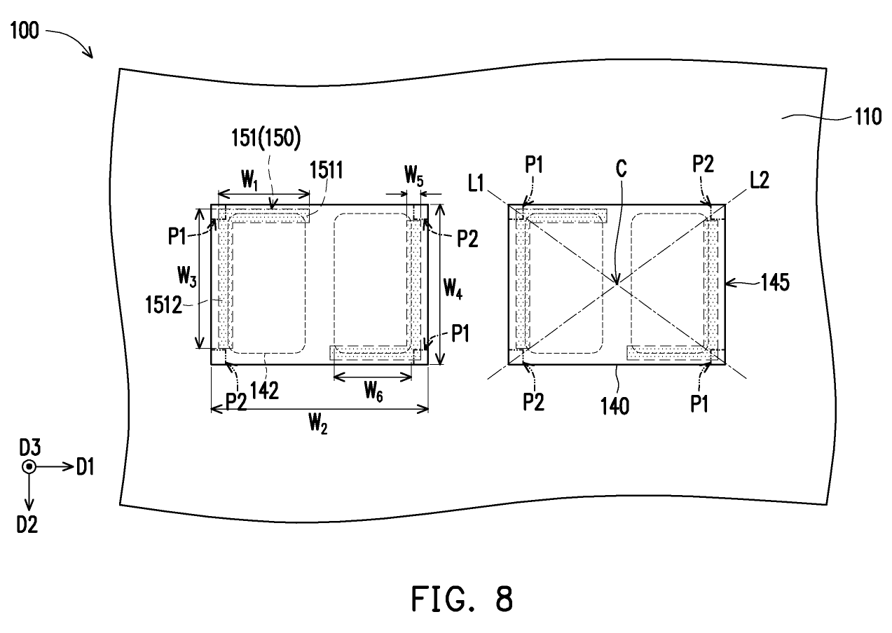

FIG. 1 is a flowchart of a method of manufacturing a light emitting element substrate according to an embodiment of the disclosure. FIG. 2 to FIG. 7 are schematic diagrams of the manufacturing process of the light emitting element substrate in FIG. 1. FIG. 8 is a top view of the light emitting element substrate in FIG. 7. Herein, a first direction D1, a second direction D2, and a third direction D3 perpendicular to each other are provided to facilitate component description. Regarding the method of manufacturing the light emitting element substrate 100 of this embodiment, first, as shown in FIG. 1 and FIG. 2, step S210 is performed to provide a substrate 110. Next, step S220 is performed to dispose a mask layer 120 on the substrate 110. The mask layer 120 forms a plurality of patterned openings 122. A material of the mask layer 120 is, for example, a photoresist, but not limited thereto. FIG. 2 schematically shows the four patterned openings 122, but the number of the patterned openings 122 is not limited thereto. The patterned openings 122 are grouped in pairs. The mask layer 120 includes a mask body 121 and a plurality of protrusions 123, and the mask body 121 is connected to the substrate 110. The protrusions 123 are connected to the mask body 121 located between two patterned openings 122 in the same group and extend along the third direction D3. The mask layer 120 may be formed by any known method. The mask body 121 and the protrusions 123 may be formed simultaneously as an integral formation, but not limited thereto.

After the mask layer 120 is disposed completely, as shown in FIG. 1 and FIG. 3, step S230 is performed to dispose an adhesive layer 130 on the substrate 110. The adhesive layer 130 fills the patterned openings 122 and covers the mask body 121. The adhesive layer 130 of this embodiment includes a first adhesive portion 131 and a second adhesive portion 132 connected to each other, and the first adhesive portion 131 and the second adhesive portion 132 may be formed simultaneously on the substrate 110. The first adhesive portion 131 covers a portion of the mask layer 120 (i.e., the mask body 121), and the second adhesive portion 132 is at least partially located within the patterned openings 122 of the mask layer 120. A top surface 133 of the adhesive layer 130 is flush with a top surface 124 of the protrusions 123 of the mask layer 120, and the top surface 124 of the protrusions 123 is exposed from the adhesive layer 130.

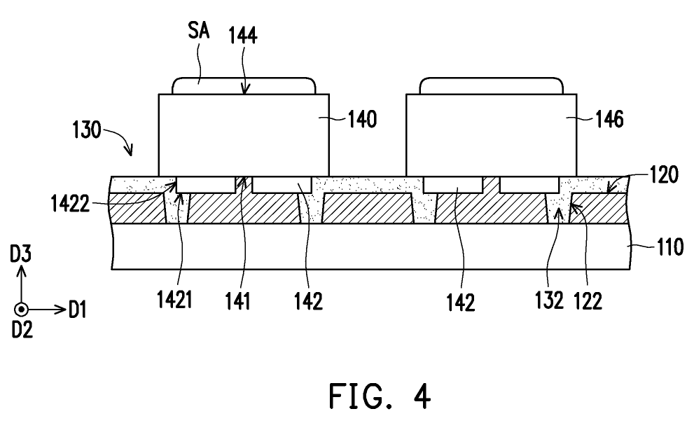

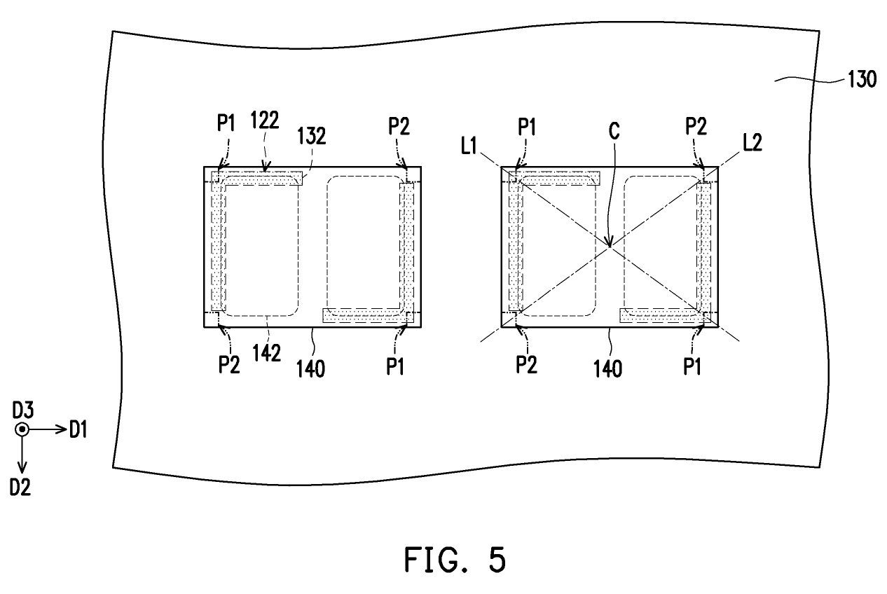

After the adhesive layer 130 is disposed completely, as shown in FIG. 1, FIG. 4, and FIG. 5, step S240 is performed to dispose a plurality of light emitting elements 140, and the light emitting elements 140 contact the adhesive layer 130 and the mask layer 120. Each of the light emitting elements 140 includes a light emitting body 146, at least one pad 142, two first diagonal regions P1, and two second diagonal regions P2. A shape of a bottom surface 141 of the light emitting element 140 is rectangular, but not limited thereto. The two first diagonal regions P1 and the two second diagonal regions P2 are located on the bottom surface 141 and respectively correspond to four corners of the bottom surface 141. The two first diagonal regions P1 are located on a first diagonal line L1 of the bottom surface 141, and the two second diagonal regions P2 are located on a second diagonal line L2 of the bottom surface 141. The first diagonal line L1 and the second diagonal line L2 are different from the first direction D1, the second direction D2, and the third direction D3. The first diagonal line L1 and the second diagonal line L2 are intersected at a geometric center C of each of the light emitting elements 140.

The at least one pad 142 is disposed on the bottom surface 141. The light emitting element 140 is, for example, a light emitting diode (LED), but not limited thereto. The at least one pad 142 of this embodiment includes two pads 142, but not limited thereto. Each of the pads 142 includes a bottom edge 1421 and a side edge 1422 connected to each other, and the side edge 1422 contacts the bottom surface 141. The bottom edge 1421 corresponds to the bottom surface 141 and is a plane, but not limited thereto. In an embodiment not shown, the bottom edge 1421 of the pad 142 may be a curved surface. FIG. 4 and FIG. 5 schematically show the two light emitting elements 140 corresponding to two sets of patterned openings 122, and schematically mark the adhesive layer 130 (the second adhesive portion 132) located within the patterned openings 122 with dot. The number of light emitting elements 140 is not limited to this embodiment.

The first diagonal regions P1 and the second diagonal regions P2 are away from the geometric center C of the light emitting element 140. At least a portion of orthogonal projections of the two first diagonal regions P1 to the substrate 110 is located within orthogonal projections of one pair of the patterned openings 122 to the substrate 110. A portion of the bottom surface 141 of the light emitting element 140 and portions of the bottom edge 1421 and the side edge 1422 of the pad 142 contact the second adhesive portion 132 of the adhesive layer 130, and the mask layer 120 contacts another portion of the bottom surface 141 of the light emitting element 140 and another portions of the bottom edge 1421 and the side edge 1422 of the pad 142. The top surface 124 of the protrusion 123 of the mask layer 120 contacts the bottom surface 141 of the light emitting element 140 and is located between the two pads 142.

The light emitting element 140 of this embodiment is, for example, transferred from a connection board (not shown) to the substrate 110. The light emitting element 140 and the connection board may be connected through an adhesive SA, so that the connection board may drive the light emitting element 140 to move. When the light emitting element 140 is to be disposed on the substrate 110, the connection board first moves above the substrate 110, then moves downward to connect the light emitting element 140 to the adhesive layer 130, and finally the connection board is removed. Therefore, after the light emitting element 140 of this embodiment is disposed completely, a portion of the adhesive SA remains on a top surface 144 of the light emitting body 146 of the light emitting element 140. The top surface 144 is opposite to the bottom surface 141. The setting method of the light emitting element 140 is not limited thereto.

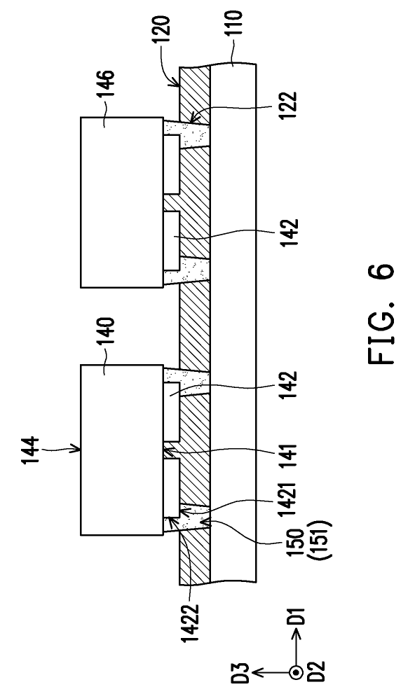

After the light emitting element 140 is disposed completely, as shown in FIG. 1 and FIG. 6, step S250 is performed to remove the adhesive SA on the light emitting elements 140. After removing the adhesive SA, step S260 is performed to remove portions of the adhesive layer 130 to form a plurality of adhesive structures 150. According to different setting methods of the light emitting element 140, after the light emitting element 140 is disposed completely (i.e., step S240 is performed completely), if there is no adhesive SA remains, step S260 may also be directly performed.

Each of the adhesive structures 150 includes two first adhesive members 151 separated from each other. The first adhesive members 151 of the adhesive structure 150 are formed by portions remaining from the adhesive layer 130 (for example, the second adhesive portions 132). The shape of the first adhesive members 151 corresponds to the shape of the patterned openings 122 of the mask layer 120. After the adhesive structures 150 are formed completely, as shown in FIG. 1 and FIG. 7, step S270 is performed to remove the mask layer 120 to form a gap G between the light emitting element 140 and the substrate 110. At this point, the light emitting element substrate 100 is manufactured completely.

FIG. 7 and FIG. 8 schematically show the two light emitting elements 140, but the number of the light emitting elements 140 is not limited thereto. FIG. 8 schematically represents the adhesive structures 150 filled with dots. As shown in FIG. 7 and FIG. 8, the light emitting element substrate 100 includes the substrate 110, the adhesive structures 150, and the light emitting elements 140. The adhesive structures 150 are disposed on the substrate 110, and each of the adhesive structures 150 includes two first adhesive members 151 separated from each other. Each of the light emitting elements 140 includes the light emitting body 146, the two pads 142, and the two first diagonal regions P1. The two first diagonal regions P1 are located on the bottom surface 141 of the light emitting body 146 and located on the first diagonal line L1, and the pads 142 are disposed on the bottom surface 141. The pad 142 includes the bottom edges 1421 and the side edges 1422 connected to each other, and the side edge 1422 contacts the bottom surface 141. The two first adhesive members 151 cover at least a portion of the corresponding two first diagonal regions P1, and connect portions of the side edges 1422 and the bottom edges 1421. The portions of the two pads 142 connect to the adhesive structures 150, and there is the gap G between another portions of the two pads 142 and the substrate 110.

A bottom surface 143 of the light emitting element 140 is formed by portions of the bottom surface 141 of the light emitting body 146 that are not connected to the two pads 142 and the bottom edges 1421 and the side edges 1422 of the two pads 142. A contact area between the adhesive structure 150 and the bottom surface 143 is greater than or equal to 30% of an area of the bottom surface 143 and less than or equal to 40% of the area of the bottom surface 143. The contact area between the adhesive structure 150 and the bottom surface 143 is preferably one-third of the area of the bottom surface 143.

The substrate 110 of this embodiment is, for example, an intermediate substrate. In a manufacturing process of a display device (not shown), the substrate 110 is used to temporarily connect the light emitting elements 140, and the light emitting elements 140 may be removed from the substrate 110 in subsequent processes and transferred to other circuit substrates (not shown). To facilitate the light emitting elements 140 to be smoothly removed from the substrate 110, the first adhesive members 151 of the light emitting element substrate 100 of this embodiment only connect to portions of the pads 142 of the light emitting elements 140, and form gaps G between the light emitting elements 140 and the substrate 110, to reduce the connection strength between the light emitting elements 140 and the substrate 110, thereby making the light emitting elements 140 easy to be removed to facilitate subsequent processes. The two first adhesive members 151 cover at least the portions of the two first diagonal regions P1 of each light emitting elements 140, so that the light emitting element 140 is stably connected to the substrate 110 without being skewed relative to the substrate 110 or falling off from the substrate 110.

The adhesive strength of these adhesive structures 150 may be relatively strong. For example, the adhesive strength of these adhesive structures 150 may be greater than 20 Newtons. Thereby, even though the adhesive structures 150 only connect to the portions of the pads 142, the connection stability between the adhesive structures 150 and the light emitting elements 140 may still be ensured.

As shown in FIG. 8, the shape of the first adhesive members 151 of the adhesive structure 150 of this embodiment is L-shaped, but not limited thereto. In an embodiment not shown, the shape of the first adhesive members 151 may be any polygon. The first diagonal regions P1 and second diagonal regions P2 of each light emitting element 140 are away from the geometric center C and adjacent to a side 145 of the light emitting body 146 of the light emitting element 140, and the side 145 is connected between the bottom surface 141 and the top surface 144 of the light emitting body 146. The two first adhesive members 151 respectively cover portions of the two first diagonal regions P1, and the second diagonal regions P2 are exposed from the first adhesive members 151, but not limited thereto.

As shown in FIG. 7 and FIG. 8, each of the first adhesive members 151 includes a connected first portion 1511 and a second portion 1512. The first portion 1511 extends along the first direction D1, and the second portion 1512 extends along the second direction D2. A length of the first portion 1511 in the first direction D1 is W₁, an element length of the light emitting element 140 in the first direction D1 is W₂, wherein W₂/3 ≦ W₁ ≦ W₂/2. A length of the second portion 1512 in the second direction D2 is W₃, an element width of the light emitting element 140 in the second direction D2 is W₄, wherein W₄/2 ≦ W₃≦ W₄. A length of the second portion 1512 in the first direction D1 is W₅, a pad length of the pad 142 in the first direction D1 is W₆, wherein W₅ ≦ W₆/3. A pad thickness of the pad 142 in the third direction D3 is W₇, a structure thickness of the adhesive structure 150 in the third direction D3 is W₈, wherein W₇ ≦ W₈ ≦ W₄.

Thereby, the first adhesive members 151 may be stably connected and maintained the light emitting elements 140, so that the light emitting elements 140 may be easily removed from the substrate 110 to facilitate subsequent processes. The structure and disposing position of the first adhesive members 151 are not limited to this embodiment. In an embodiment not shown, the two first adhesive members 151 may respectively completely cover the two first diagonal regions P1. The edges of the first adhesive members 151 may be aligned with the sides 145 of the light emitting elements 140. In an embodiment not shown, the two first adhesive members 151 may respectively cover a part of the two second diagonal regions P2. In an embodiment not shown, the length W ₁ of the first portion 1511 may be equal to the length W₃ of the second portion.

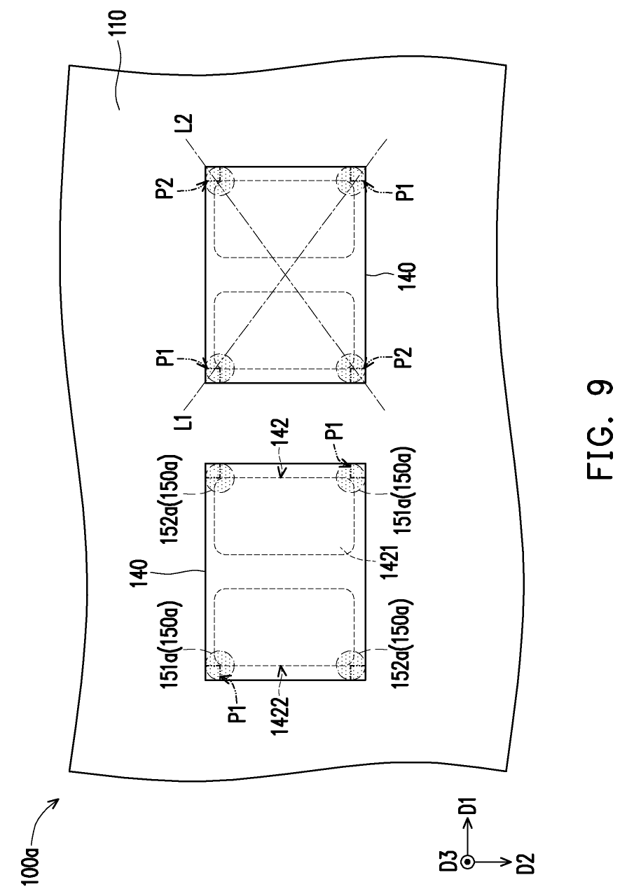

FIG. 9 is a top view of a light emitting element substrate according to an embodiment of the disclosure. Please refer to FIG. 8 and FIG. 9 at the same time, the light emitting element substrate 100a of this embodiment is similar to the previous embodiment. The difference between the two is that the adhesive structure 150a of this embodiment further includes two second adhesive members 152a separated from each other. The two second adhesive members 152a respectively cover at least a portion of each two second diagonal regions P2 of the light emitting element 140, and are connected to portions of the bottom edge 1421 and the side edge 1422 of the pad 142. The shapes of the first adhesive members 151a and the second adhesive members 152a are circular, but not limited thereto. In an embodiment not shown, the shapes of the first adhesive members 151a and the second adhesive members 152a may be rectangular or any polygon. The light emitting element substrate 100a of this embodiment has the same effects as the previous embodiment, and is not repeated herein.

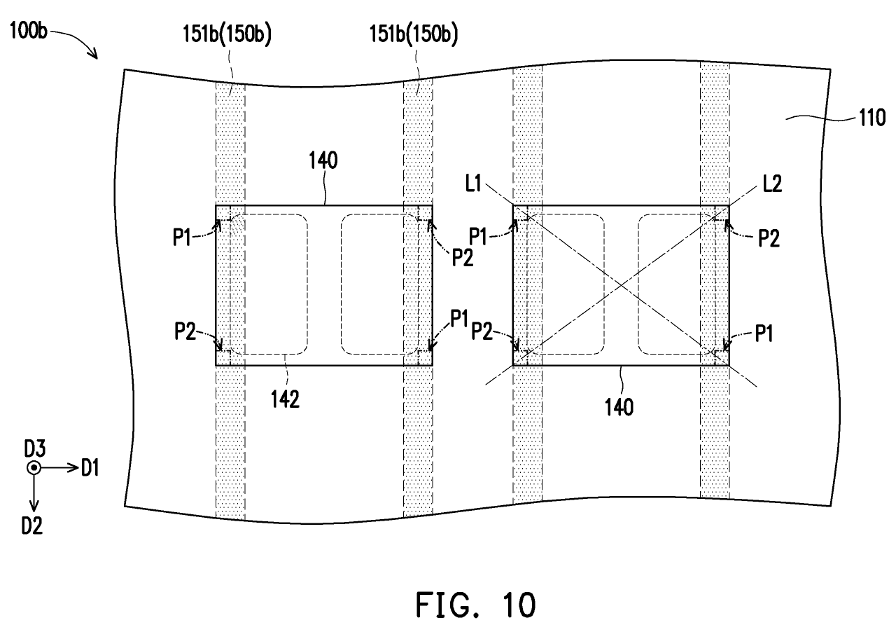

FIG. 10 is a top view of a light emitting element substrate according to an embodiment of the disclosure. Please refer to FIG. 8 and FIG. 10 at the same time, the light emitting element substrate 100b of this embodiment is similar to the previous embodiment. The difference between the two is that the two first adhesive members 151b of the adhesive structure 150b of this embodiment respectively cover at least portions of the two second diagonal regions P2 in the first direction D1. The light emitting elements 140 are arranged in an array, and the two first adhesive members 151 of each adhesive structure 150 extend in the first direction D1 and connect to the adhesive structures 150 of adjacent adhesive structure 150 in the first direction D1. The first adhesive members 151 completely cover the first diagonal regions P1 and the second diagonal regions P2, but not limited thereto. The light emitting element substrate 100b of this embodiment has the same effects as the previous embodiment, and is not repeated herein.

In summary, the first adhesive members of the light emitting element substrate of the disclosure only connect the portions of the pads of the light emitting elements to reduce the connection strength between the light emitting elements and the adhesive structure, making the light emitting elements easy to be removed to facilitate subsequent processes. The two first adhesive members connect to the two first diagonal regions of each of the light emitting elements, so that the light emitting elements are stably connected to the substrate. Thereby, the substrate may stably maintain the light emitting elements and make the light emitting elements easy to be removed from the substrate to facilitate subsequent processes.

What is claimed is:

1. A light emitting element substrate, comprising:
a substrate;
a plurality of adhesive structures disposed on the substrate, each of the adhesive structures comprises two first adhesive members separated from each other; and
a plurality of light emitting elements, each of the light emitting elements comprises a light emitting body, at least one pad, and two first diagonal regions, the two first diagonal regions are located on a bottom surface of the light emitting body and positioned on a first diagonal line, the at least one pad is disposed on the bottom surface, each of the at least one pad comprises a bottom edge and a side edge connected to each other, the side edge is contacted to the bottom surface, the two first adhesive members cover at least a portion of the corresponding two first diagonal regions and connect portions of the side edge and the bottom edge.

2. The light emitting element substrate according to claim 1, wherein the at least one pad comprises two pads, portions of the two pads connect the adhesive structures, there is a gap between another portions of the two pads and the substrate.

3. The light emitting element substrate according to claim 1, wherein each of the adhesive structures comprises two second adhesive members separated from each other, each of the light emitting elements comprises two second diagonal regions located on the bottom surface, the two second diagonal regions are positioned on a second diagonal line, the first diagonal line and the second diagonal line intersect at a geometric center of each of the light emitting elements, the two second adhesive members respectively cover at least a portion of the two second diagonal regions.

4. The light emitting element substrate according to claim 1, wherein each of the light emitting elements comprises two second diagonal regions located on the bottom surface, the two second diagonal regions are positioned on a second diagonal line, the two first adhesive members respectively covering at least a portion of the two second diagonal regions in a first direction.

5. The light emitting element substrate according to claim 1, wherein the light emitting elements are arranged in an array, the two first adhesive members of each of the adhesive structures extend in a first direction and connect each of the adhesive structures adjacent in the first direction, the first diagonal line is different from the first direction.

6. The light emitting element substrate according to claim 1, wherein each of the two first adhesive members comprises a first portion and a second portion connected to each other, the first portion extends along a first direction, the second portion extends along a second direction, the first direction is different from the second direction.

7. The light emitting element substrate according to claim 6, wherein a length of the first portion in the first direction is W₁ an element length of each of the light emitting elements in the first direction is W₂ wherein W₂/3 ≦ W₁ ≦ W₂2/.

8. The light emitting element substrate according to claim 6, wherein a length of the second portion in the second direction is W₃ an element width of each of the light emitting elements in the second direction is W₄ wherein W₄/2 ≦ W₃ ≦ W₄.

9. The light emitting element substrate according to claim 6, wherein a length of the second portion in the first direction is W₅ a pad length of each of the at least one pad in the first direction is W₆ wherein W₅ ≦ W₆3/.

10. The light emitting element substrate according to claim 6, wherein an element width of each of the light emitting elements in the second direction is W₄ a pad thickness of each of the at least one pad in a third direction is W₇ a structure thickness of each of the adhesive structures in the third direction is W8, wherein W₇ ≦ W₈ ≦ W₄ the third direction is different from the first direction and the second direction.

11. The light emitting element substrate according to claim 1, wherein an adhesive strength of the adhesive structures is greater than 20 Newtons.

12. The light emitting element substrate according to claim 1, wherein a contact area between each of the adhesive structures and a bottom surface of each of the light emitting elements is greater than or equal to 30% of an area of the bottom surface and less than or equal to 40% of the area of the bottom surface.

13. A method for manufacturing a light emitting element substrate, comprising:
providing a substrate;
disposing a mask layer on the substrate, the mask layer forms a plurality of patterned openings;
disposing an adhesive layer on the substrate, the adhesive layer fills the patterned openings;
disposing a plurality of light emitting elements, the light emitting elements are contacted to the adhesive layer and the mask layer, each of the light emitting elements comprises a light emitting body, at least one pad and two first diagonal regions, the at least one pad is disposed on a bottom surface of the light emitting body, each of the at least one pad comprises a bottom edge and a side edge connected to each other, the side edge is contacted to the bottom surface, the two first diagonal regions are located on the bottom surface and located on a first diagonal line;
removing portions of the adhesive layer to form a plurality of adhesive structures, each of the adhesive structures comprises two first adhesive members separated from each other, the two first adhesive members of each of the adhesive structures cover at least a portion of the two first diagonal regions of corresponding each of the light emitting elements and connect a portion of the side edge and the bottom edge;
removing the mask layer.

14. The method for manufacturing the light emitting element substrate according to claim 13, wherein the mask layer comprises a plurality of protrusions, when the light emitting elements are disposed on the substrate, each of the protrusions contacts the bottom surface of each of the light emitting elements.

15. The method for manufacturing the light emitting element substrate according to claim 13, wherein the adhesive layer comprises a connected first adhesive portion and a second adhesive portion, the first adhesive portion covers a portion of the mask layer, the second adhesive portion is at least partially located within the patterned openings of the mask layer and adapted to contact the light emitting elements.
